(19) United States
(12) Patent Application Publication
(10) Pub. No.: US 2026/0334272 A1
(43) Pub. Date: Oct. 22, 2026

(54) BONDING APPARATUS AND BONDING METHOD

(71) Applicant: WUHAN XINXIN SEMICONDUCTOR MANUFACTURING CO., LTD., WUHAN (CN)

(72) Inventors: CHAO TAO, WUHAN (CN); JUNZHOU LONG, WUHAN (CN); LI WANG, WUHAN (CN)

(21) Appl. No.: 19/698,848

(22) Filed: Jun. 5, 2026

Related U.S. Application Data
(63) Continuation of application No. PCT/CN2023/138940, filed on Dec. 14, 2023.

(30) Foreign Application Priority Data
Dec. 7, 2023 (CN) 202311684199.X

(51) Int. Cl. H10W 72/00

(52) U.S. Cl. CPC H10W 72/07178; H10W 72/07173; H10W 72/07183

(57) ABSTRACT

A bonding apparatus includes: a movable pick-up stage carrying a first element; a carrier stage carrying a second element; and an image acquisition device for reading an alignment mark of the first element and an alignment mark of the second element. The alignment mark of the first element and the alignment mark of the second element are in one coordinate system. The bonding apparatus determines an alignment offset between the first element and the second element based on coordinate information of the alignment mark of the first element, coordinate information of the alignment mark of the second element, and preset calibration information of the image acquisition device. The bonding apparatus adjusts the movable pick-up stage and/or the carrier stage to perform an alignment compensation operation based on the alignment offset, enabling the first element and the second element to be aligned and bonded to each other.

### CROSS REFERENCE TO RELATED APPLICATIONS

The present application is a continuation application of the international patent application No. PCT/CN2023/138940, filed on Dec. 14, 2023, which claims the priority of the Chinese patent application No. 202311684199.X, filed on Dec. 7, 2023, in the title of “BONDING APPARATUS AND BONDING METHOD”, contents of which are incorporated herein by its entireties.

### TECHNICAL FIELD

Embodiments of the present disclosure relate to the technical field of semiconductor manufacturing, and more specifically, to a bonding apparatus and a bonding method.

### BACKGROUND

As semiconductor technology enters the post-Moore era, in order to meet the demands for high integration density and high performance, chip structures are developing towards three-dimensional directions. Manufacturing stacked chips through bonding technology is one of the important technologies of the “More than Moore” approach. Bonding accuracy is an important parameter of the bonding process and has a great impact on the application of bonding technology.

### SUMMARY

In a first aspect, the present disclosure provides a bonding apparatus, including: a movable pick-up stage, configured to move a first element; a carrier stage, configured to move a second element; and an image acquisition device, configured to read at least one alignment mark of the first element and at least one alignment mark of the second element that are respectively located on two sides of the image acquisition device. The read at least one alignment mark of the first element and the read at least one alignment mark of the second element are located in one coordinate system; the bonding apparatus is configured to determine an alignment offset between the first element and the second element based on coordinate information of the at least one alignment mark of the first element, coordinate information of the at least one alignment mark of the second element, and preset calibration information of the image acquisition device. The bonding apparatus is configured to drive at least one of the movable pick-up stage and the carrier stage to move for adjustment to perform an alignment compensation operation based on the alignment offset, enabling the first element and the second element to be aligned and bonded to each other.

In a second aspect, the present disclosure provides a bonding method, applied to a bonding apparatus. The bonding method includes: reading at least one alignment mark of a first element and at least one alignment mark of a second element, where, the first element and the second element are located on different sides of an image acquisition device of the bonding apparatus, and the read at least one alignment mark of the first element and the read at least one alignment mark of the second element are located in one coordinate system; determining an alignment offset between the first element and the second element based on coordinate information of the at least one alignment mark of the first element, coordinate information of the at least one alignment mark of the second element, and preset calibration information of the image acquisition device; and driving, by the bonding apparatus, at least one of the first element and the second element to move for adjustment to perform an alignment compensation operation based on the alignment offset, so as to enable the first element and the second element to be aligned and bonded to each other.

### BRIEF DESCRIPTION OF THE DRAWINGS

In order to more clearly illustrate the technical solutions in the embodiments of the present disclosure, the drawings that are required for the description of the embodiments will be briefly introduced below. Apparently, the drawings in the following description are merely some embodiments of the present disclosure. For those skilled in the art, other drawings may be obtained from these drawings without creative efforts.

FIG. 1 is a structural schematic view of a bonding apparatus according to a first embodiment of the present disclosure.

FIG. 2 is a structural schematic view of the bonding apparatus according to a second embodiment of the present disclosure.

FIG. 3 is a structural schematic view showing an alignment mark being transferred to a same plane, according to an embodiment of the present disclosure.

FIG. 4 is a schematic diagram of a calibration coordinate system corresponding to the bonding apparatus according to an embodiment of the present disclosure.

FIG. 5 is a flow chart of a bonding method according to an embodiment of the present disclosure.

FIG. 6 is a schematic view of the bonding apparatus determining coordinate information of a first element and a second element, according to an embodiment of the present disclosure.

FIG. 7 is a schematic view showing a process of the bonding apparatus bonding the first element to a preset surface position of the second element, according to an embodiment of the present disclosure.

FIG. 8 is a schematic view of the coordinate information of the first element in the calibration coordinate system, when the first element being bonded to the preset surface position of the second element, according to an embodiment of the present disclosure.

Reference numerals in the drawings: bonding apparatus 10, movable pick-up stage 100, first driving assembly 110, carrier stage 200, second driving assembly 210, image acquisition device 300, upward-looking image acquisition assembly 310, upward-looking image acquisition unit 311, first reflection unit 312, downward-looking image acquisition assembly 320, downward-looking image acquisition unit 321, second reflection unit 322, image acquisition driving member 330, first element 400, second element 500, machine station 600, base 610, machine frame 620, supply platform 700.

### DETAILED DESCRIPTIONS

The technical solutions in the embodiments of the present disclosure may be clearly and completely described below with reference to the accompanying drawings in the embodiments of the present disclosure. Apparently, the described embodiments may be only a part of the embodiments of the present disclosure, rather than all of the embodiments. Based on the embodiments of the present disclosure, all other embodiments obtained by those skilled in the art without making creative efforts may fall within the protection scope of the present disclosure.

The terms “first”, “second”, and “third” in the present disclosure may be used for descriptive purposes only, and may not be construed as indicating or implying relative importance or implicitly indicating the number of the indicated technical features. Thus, features defined with “first”, “second”, and “third” may explicitly or implicitly include at least one such feature. In the description of the present disclosure, “a plurality of” or “multiple” may mean at least two, for example, two, three, etc., unless otherwise specifically defined. All directional indications (such as up, down, left, right, front, back, etc.) in the embodiments of the present disclosure may be used only to explain the relative positional relationship, movement conditions, etc. among components under a specific posture (as shown in the drawings). If the specific posture changes, the directional indications may change accordingly. In addition, the terms “include”, “comprise”, and “have”, as well as any variations thereof, may be intended to cover non-exclusive inclusion. For example, a process, method, system, product, or device including a series of operations or units may not be limited to the listed operations or units, but may optionally include operations or units not listed, or may optionally include other operations or units inherent to such process, method, product, or device.

As used herein, references to “embodiment” may mean that a particular feature, structure, or characteristic described in connection with the embodiment may be included in at least one embodiment of the present disclosure. The appearances of this phrase in various places in the specification may not necessarily refer to the same embodiment, nor may they be independent or alternative embodiments mutually exclusive with other embodiments. It may be explicitly and implicitly understood by those skilled in the art that the embodiments described herein may be combined with other embodiments.

The present disclosure may be described in detail below with reference to the accompanying drawings and embodiments.

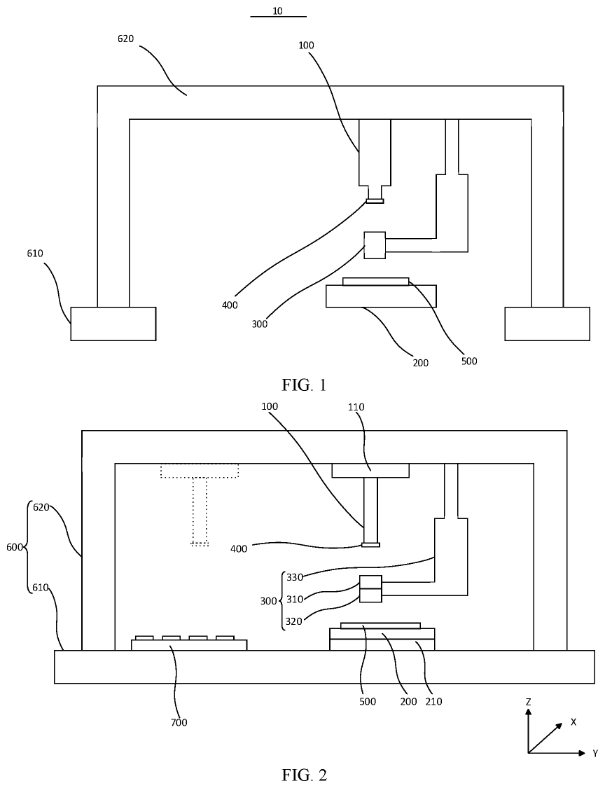

As shown in FIG. 1, FIG. 1 is a schematic structural view of a bonding apparatus according to a first embodiment of the present disclosure.

As shown in FIG. 1, the bonding apparatus 10 may include: a movable pick-up stage 100, a carrier stage 200, and an image acquisition device 300. The movable pick-up stage 100 may be configured to pick up and move a first element 400. The carrier stage 200 may be configured to carry and move a second element 500. The image acquisition device 300 may be configured to read an alignment mark of the first element 400 and an alignment mark of the second element 500 that may be located respectively on two sides of the image acquisition device. The read alignment mark of the first element 400 and the read alignment mark of the second element 500 may be located in a same coordinate system. The bonding apparatus 10 may determine an alignment offset between the first element 400 and the second element 500 based on coordinate information of the alignment mark of the first element 400, coordinate information of the alignment mark of the second element 500, and preset calibration information of the image acquisition device 300.

The bonding apparatus 10 may drive the movable pick-up stage 100 and/or the carrier stage 200 to move for adjustment, so as to perform an alignment compensation operation based on the alignment offset, so as to align and bond the first element 400 and the second element 500 with each other. The alignment offset may be a coordinate difference between the first element 400 and the second element 500 in the same coordinate system. The calibration information may be a coordinate system (measurement) scale of the image acquisition device 300 and may be determined by internal parameters and/or external parameters of the image acquisition device 300.

In some embodiments, the movable pick-up stage 100 may be arranged on a machine frame 620, and the image acquisition device 300 may also be arranged on the machine frame 620. The machine frame 620 may be arranged on a base 610.

It is understandable that, in some embodiments, the first element 400 may be a to-be-bonded wafer or a to-be-bonded chip. Correspondingly, the second element 500 may be a to-be-bonded wafer or a to-be-bonded chip.

It should be noted that FIG. 1 only shows an embodiment in which the movable pick-up stage 100 is disposed on a top of the machine frame 620 and the carrier stage 200 is arranged on the base 610. In another embodiment, the movable pick-up stage 100 may be arranged on the base 610, and the carrier stage 200 may be arranged on the machine frame 620. Arrangement of the movable pick-up stage 100 and the carrier stage 200 may be determined to enable the first element 400 and the second element 500 to be moved to an alignment position at which the first element 400 and the second element 500 can be aligned with each other. Therefore, positions of the movable pick-up stage 100 and the carrier stage 200 may not be limited in the present disclosure.

Specifically, in response to the bonding apparatus 10 performing a pick-up operation, the bonding apparatus 10 may drive the movable pick-up stage 100 to firstly pick up the to-be-bonded first element 400 at a pick-up position and then may drive the movable pick-up stage 100 to reach the alignment position. The bonding apparatus 10 may further drive the carrier stage 200, which carries the to-be-bonded second element 500, to reach the alignment position. After the first element 400 and the second element 500 reach the alignment position, the bonding apparatus 10 may drive the image acquisition device 300 to reach a working position. In response to the image acquisition device 300 being driven to the working position, the image acquisition device 300 may simultaneously identify and read the alignment mark of the first element 400 and the alignment mark of the second element 500 that are respectively located on two sides of the image acquisition device 300. The read alignment mark of the first element 400 and the read alignment mark of the second element 500 may be located in the same coordinate system. The coordinate information of the alignment mark of the first element in the coordinate system and the coordinate information of the alignment mark of the second element in the coordinate system may be obtained. The bonding apparatus 10 may determine the alignment offset between the first element 400 and the second element 500 based on the coordinate information of the alignment mark of the first element, the coordinate information of the alignment mark of the second element, and the preset calibration information of the image acquisition device 300. After obtaining the alignment offset, the bonding apparatus 10 may drive, based on the alignment offset, the movable pick-up stage 100 and/or the carrier stage 200 to move for adjustment to perform the alignment compensation operation, so as to enable the first element 400 and the second element 500 to be aligned with each other. After the first element 400 and the second element 500 are aligned with each other, the movable pick-up stage 100 and/or the carrier stage 200 may be moved along a height direction, such as being moved downward, such that the moved-down first element 400 and second element 500 may contact and may be bonded with each other.

In some embodiments, the movable pick-up stage 100 and/or the carrier stage 200 may firstly be moved vertically to reach a bonding position, and then the alignment compensation operation may be performed. The first element and the second element may be aligned with each other, and then the first element 400 may be moved downward to be bonded to the second element 500.

In some embodiments, the alignment compensation operation may be performed simultaneously with the movable pick-up stage 100 and/or the carrier stage 200 being moved in the height direction, such that the first element 400 and the second element 500 may be moved to align with each other while being moved in the height direction, such that a bonding efficiency may be improved.

The pick-up position may be a position at which the movable pick-up stage 100 picks up the first element 400. The alignment position may be the position at which the first element 400 and the second element 500 are aligned to each other. The working position may be a position at which the image acquisition device 300 captures the alignment mark of the first element 400 and the alignment mark of the second element 500. The working position may be located between the first element 400 and the second element 500 before the first element 400 and the second element 500 are bonded to each other. More precisely, the working position may be a position between the first element 400 and the second element 500 when the first element 400 and the second element 500 are moved to reach the alignment position.

In addition, the coordinate system in which the alignment mark of the first element 400 and the alignment mark of the second element 500 are both placed may be a field of view of a same camera. That is, the alignment mark of the first element 400 and the alignment mark of the second element 500 may be transferred into the field of view of the same camera. A coordinate system may be defined within the field of view of the camera. In this way, the coordinate information of the alignment mark of the first element 400 and the coordinate information of the alignment mark of the second element 500 may be determined.

In some embodiments, the movable pick-up stage 100 may be driven to move for adjustment, or the carrier stage 200 may be driven to move for adjustment, or both the movable pick-up stage 100 and the carrier stage 200 may be driven to move for adjustment simultaneously, such that the first element 400 and the second element 500 may be quickly aligned with each other.

In some embodiments, before the movable pick-up stage 100 drives the first element 400 to move in the height direction, such as move downward, the bonding apparatus 10 may need to drive the image acquisition device 300 to move to reach an initial position, and that is, the image acquisition device 300 may be moved away from the working position, such that the image acquisition device 300 may be prevented from obstructing downward movement of the first element 400.

That is, the alignment mark of the first element 400 and the alignment mark of the second element 500 may need to be obtained for once only, and the alignment offset between the first element 400 and the second element 500 may be determined based on the alignment mark of the first element, the alignment mark of the second element, and the preset calibration information. Consequently, alignment between the first element 400 and the second element 500 may be achieved in a single operation based on the alignment offset, time consumption caused by multiple alignments may be avoided.

In the present embodiment, according to the bonding apparatus provided by the present disclosure, an integrated image acquisition device may be provided and may obtain the alignment mark of the first element and the alignment mark of the second element that are located on two sides of the image acquisition device within the same coordinate system. The alignment mark of the first element and the alignment mark of the second element may be compared with the preset calibration information. The bonding apparatus may determine the alignment offset between the first element 400 and the second element 500. In this way, the bonding apparatus may complete alignment and bonding of the first element 400 and the second element 500 in one single operation based on the alignment offset. Furthermore, multiple alignments for each to-be-bonded second element 500 may be avoided, such that time consumption may be effectively reduced, the bonding efficiency may be improved, and a throughput may be increased.

As shown in FIG. 2, FIG. 2 is a structural schematic view of the bonding apparatus according to a second embodiment of the present disclosure.

As shown in FIG. 2, the bonding apparatus 10 may include: the movable pick-up stage 100, the carrier stage 200, the image acquisition device 300, and a machine station 600. The movable pick-up stage 100 may be configured to pick up and move the first element 400. The carrier stage may be configured to carry and move the second element 500. The image acquisition device 300 may be configured to read the alignment mark of the first element 400 and the alignment mark of the second element 500 that may be located on two sides of the image acquisition device 300. The read alignment mark of the first element 400 and the read alignment mark of the second element 500 may be located in one same coordinate system. The bonding apparatus may determine the alignment offset between the first element 400 and the second element 500 based on the coordinate information of the alignment mark of the first element 400, the coordinate information of the alignment mark of the second element 500, and the preset calibration information of the image acquisition device 300. The machine station 600 may include the base 610 and the machine frame 620. The machine frame 620 may be arranged on the base 610. The movable pick-up stage 100 may be arranged on the machine frame 620 and may face the base 610. The carrier stage 200 may be arranged on the base 610. The image acquisition device 300 may be arranged on the machine frame 620 and may face the base 610.

It should be noted that FIG. 2 only shows an embodiment in which the movable pick-up stage 100 is arranged on the top of the machine frame and the carrier stage 200 is arranged on the base. In another embodiment, the movable pick-up stage 100 may be arranged on the base, and the carrier stage 200 may be arranged on the machine frame. Arrangement of the movable pick-up stage 100 and the carrier stage 200 may enable the first element 400 and the second element 500 to be moved to reach the bonding position. Therefore, positions of the movable pick-up stage 100 and the carrier stage 200 may not be limited in the present disclosure.

In some embodiments, the bonding apparatus may be configured to adjust, based on the alignment mark of the first element 400 and the alignment mark of the second element 500 identified by the image acquisition device 300, the first element 400 and the second element 500 at the alignment position, so as to enable the first element 400 and the second element 500 at the alignment position to be aligned with each other in the height direction.

Furthermore, in response to the bonding apparatus performing the alignment compensation operation, the first element 400 and the second element 500, which may be aligned with each other at the alignment position, may be configured to be moved to the bonding position. The image acquisition device 300 may be configured to: identify the alignment marks of the first element 400 and the alignment mark of the second element 500 at the bonding position; obtain a difference between the alignment mark of the first element 400 and the alignment mark of the second element 500; and take a comparison result between the difference and the preset calibration information as the alignment offset to perform the alignment compensation operation.

In some embodiments, in response to the bonding apparatus performing a bonding operation, the bonding apparatus may adjust the movable pick-up stage 100 and/or the carrier stage 200 based on the alignment offset, so as to perform the alignment compensation operation on the first element 400 and the second element 500 at the alignment position; and may move the movable pick-up stage 100 and/or the carrier stage 200 in the height direction to drive the first element 400 and the second element 500 to move to reach the bonding position.

Furthermore, in response to the bonding apparatus performing the bonding operation, the bonding apparatus may move the movable pick-up stage 100 and/or the carrier stage 200 in the height direction to drive the first element 400 and the second element 500 to reach the bonding position and may simultaneously adjust the movable pick-up stage 100 and/or the carrier stage 200 based on the alignment offset to perform the alignment compensation operation on the first element 400 and the second element 500.

In some embodiments, the image acquisition device 300 may be an upper-and-downward-looking image acquisition device. That is, the image acquisition device 300 may simultaneously capture an image from an upward viewing angle and an image from a downward viewing angle. Specifically, the image acquisition device 300 may include an upward-looking image acquisition assembly 310 and a downward-looking image acquisition assembly 320.

In response to the image acquisition device 300 being driven to the working position, the upward-looking image acquisition assembly 310 may be configured to identify at least one alignment mark of the first element 400 in the calibration coordinate system, and the at least one alignment mark may be two alignment marks, such as a first alignment mark and a second alignment mark. The downward-looking image acquisition assembly 320 may be configured to identify at least one alignment mark of the second element 500 in the calibration coordinate system, and the at least one alignment mark may be two alignment marks, such as a third alignment mark and a fourth alignment mark. Taking one alignment mark as an example, the upward-looking image acquisition assembly 310 may identify the first alignment mark of the first element 400, and the downward-looking image acquisition assembly 320 may identify the third alignment mark of the second element 500. Based on the first alignment mark and the third alignment mark, i.e., the captured first alignment mark and the captured third alignment mark being directly in the calibration coordinate system, the coordinate difference between the first element 400 and the second element 500 in the calibration coordinate system may be determined. Furthermore, the coordinate difference may be compared with the preset calibration information, such that the alignment offset between the first element 400 and the second element 500 may be determined.

The upward-looking image acquisition assembly 310 may include an upward-looking image acquisition unit 311 and a first reflection unit 312. In response to the image acquisition device 300 being driven to reach the working position, the upward-looking image acquisition unit 311 may be configured to identify the at least one alignment mark of the first element 400. In response to the upward-looking image acquisition unit 311 identifying the at least one alignment mark of the first element 400, the first reflection unit 312 may transfer the at least one alignment mark of the first element 400 into the calibration coordinate system. The downward-looking image acquisition assembly 320 may include a downward-looking image acquisition unit 321 and a second reflection unit 322. In response to the image acquisition device 300 being driven to the working position, the downward-looking image acquisition unit 321 may be configured to identify at least one alignment mark of the second element 500. In response to the downward-looking image acquisition unit 321 identifying the at least one alignment mark of the second element 500, the second reflection unit 322 may transfer the at least one alignment mark of the second element 500 into the calibration coordinate system. In this way, the coordinate difference between the alignment mark of the first element 400 and the alignment mark of the second element 500 in the calibration coordinate system may be determined, and the alignment offset between the first element 400 and the second element 500 may be determined.

In some embodiments, in order to achieve a larger field of view to enable alignment marks to be distributed unlimitedly, and that is, when a plurality of alignment marks need to be identified, a plurality of upward-looking image acquisition units 311 and a plurality of downward-looking image acquisition units 321 may be arranged. The number of the upward-looking image acquisition units 311 and the downward-looking image acquisition units 321 may be determined to enable the alignment marks of the first element 400 and the alignment marks of the second element 500 to be captured.

In addition, each of the first reflection unit 312 and the second reflection unit 322 may include a plurality of reflective mirrors. The number of the reflective mirrors may be determined to enable the alignment marks of the first element 400 and the alignment marks of the second element 500 to be transferred into the calibration coordinate system in the same plane.

To more clearly illustrate the alignment marks being transferred to the same plane, description is provided below by referring to the accompanying drawings.

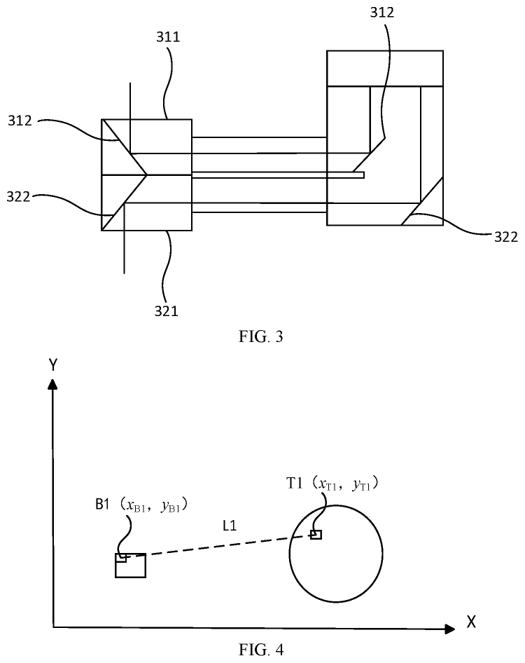

As shown in FIG. 3, FIG. 3 is a structural schematic view of transferring the alignment marks to the same plane.

As shown in FIG. 3, in an example, one upward-looking image acquisition unit, one downward-looking image acquisition unit, two first reflection units, and two second reflection units may be arranged. After the upward-looking image acquisition unit 311 identifies and captures the alignment mark of the first element 400, two first reflection units 312 may transfer the alignment mark of the first element 400 into the plane. After the downward-looking image acquisition unit 321 identifies and captures the alignment mark of the second element 500, the two second reflection units 322 may transfer the alignment mark of the second element 500 into the same plane. Furthermore, the coordinate difference between the alignment mark of the first element 400 and the alignment mark of the second element 500 in the calibration coordinate system of the plane may be obtained. The coordinate difference may be compared with the calibration information, and that is, the coordinate difference may be compared with the coordinate system scale, such that the alignment offset between the first element 400 and the second element 500 may be determined.

In some embodiments, after aligning the first element 400 and the second element 500 at the alignment position with each other and before moving the first element 400 and/or the second element 500 in the height direction, the image acquisition device may be moved to the initial position to prevent the image acquisition device from affecting the subsequent bonding operation.

The movable pick-up stage 100 may be configured to be movable along an X-direction and a Y-direction of a horizontal plane and to be movable along the height direction Z. The movable pick-up stage 100 may further be rotatable in a vertical plane perpendicular to the horizontal plane. The carrier stage 200 may be configured to be movable along the X-direction and Y-direction of the horizontal plane and to be movable along the height direction Z. The carrier stage 200 may further be rotatable in the vertical plane perpendicular to the horizontal plane. The image acquisition device 300 may be rotatable in the horizontal plane. A rotation axis of a rotation direction of the capturing component 300 may be located outside the working position. A location of the rotation axis may be determined to enable the image acquisition device 300 to rotate to reach the working position or reach the initial position.

In some embodiments, the image acquisition device 300 may move along the height direction and along the X-direction and Y-direction of the horizontal plane.

The X-direction and Y-direction may be intersecting directions within the same horizontal plane. For example, the X-direction and the Y-direction may be perpendicular to each other in the same horizontal plane. The height direction may be a direction perpendicular to the horizontal plane, and that is, the height direction may be the vertical direction. The rotation direction may refer to rotation in the horizontal plane.

In some embodiments, the movable pick-up stage 100 may be a pick-up member that is capable of flipping. That is, after picking up the first element 400 at the pick-up position, the movable pick-up stage 100 may flip, such that a bonding surface of the first element 400 may face the first driving assembly 110. After reaching the bonding position, the movable pick-up stage 100 may flip again, such that the bonding surface of the first element 400 may face the second element 500. In this way, any damage to the bonding surface of the first element 400 during movement may be avoided.

The bonding position may be the position corresponding to where the first element 400 and the second element 500 may be bonded to each other. The position at which the image acquisition device 300 reads the alignment marks may be the working position. That is, the working position may correspond to the position between the first element 400 and the second element 500. The initial position may be a position at which the image acquisition device 300 is in a non-working state.

In some embodiments, a bottom of the base 610 may be provided with a vibration isolation and damping member, so as to eliminate vibration, which may be caused by the carrier stage 200 moving the to-be-bonded second element 500 and caused by the bonding operation, such that stability of the bonding apparatus 10 may be improved.

In some embodiments, the bonding apparatus 10 may further include a first driving assembly 110 and a second driving assembly 210. The first driving assembly 110 may be arranged on the machine frame and connected to the movable pick-up stage 100. The first driving assembly 110 may be configured to carry the movable pick-up stage 100 to move along the X-direction and Y-direction of the horizontal plane, to move along the height direction, and to rotate in the vertical plane perpendicular to the horizontal plane. The second driving assembly 210 may be arranged on the base and connected to the carrier stage 200. The second driving assembly 210 may be configured to carry the carrier stage 200 to move along the X-direction and Y-direction of the horizontal plane, to move along the height direction, and to rotate in the vertical plane perpendicular to the horizontal plane.

In order to facilitate any failed component to be replaced in time, the first driving assembly 110 may be detachably arranged on the machine frame 620, and the second driving assembly 210 may also be detachably arranged on the base 610.

It should be noted that each of the first driving assembly 110 and the second driving assembly 210 may include a motor, such as a linear motor or a rotatory motor, so as to provide power for a respective driving member. It is understandable that a structure of the first driving assembly 110 in the embodiments of the present disclosure may be referred to any specific structure in the related art, as long as the first driving assembly 110 can move the movable pick-up stage 100 in the X-direction and Y-direction within the horizontal plane and a nanometer-level precision positioning can be achieved. The present disclosure does not limit a specific structure of the first driving assembly 110. Correspondingly, a structure of the second driving assembly 210 may be referred to any specific structure in the related art, as long as the second driving assembly 210 can achieve corresponding functions.

In some embodiments, any two of the X-direction, the Y-direction, and the Z-direction (height direction) may be perpendicular to each other. Specifically, the Y-direction may be a direction parallel to the Y-axis, the X-direction may be a direction parallel to the X-axis, and the Z-direction may be a direction parallel to the Z-axis.

In some embodiments, the carrier stage 200 may be a single-stage motion mechanism or a motion mechanism of any other type, as long as the carrier stage 200, when specific precision requirements being met, can move the to-be-bonded second element 500 to the preset surface position corresponding of the to-be-bonded first element 400 and bond the to-be-bonded second element 500 at the preset surface position of the to-be-bonded first element 400.

In some embodiments, the bonding apparatus 10 may further include a supply platform 700. The supply platform 700 may be arranged on the base 610 and configured to provide the to-be-bonded first element 400 for the movable pick-up stage 100. That is, a plurality of to-be-bonded first elements 400 may be placed on the supply platform 700. The movable pick-up stage 100 may pick up the first elements 400 from the supply platform 700 at the pick-up position and may carry the first elements 400 to the alignment position for alignment.

A working process of the bonding apparatus 10 will be described below.

Specifically, the upward-looking image acquisition assembly 310 of the image acquisition device 300 may have a first field of view and may be configured to read the at least one alignment mark of the to-be-bonded first element 400. The downward-looking image acquisition assembly 320 of the image acquisition device 300 may have a second field of view and may be configured to read the at least one alignment mark of the to-be-bonded second element 500. In an example, the first element may include the first alignment mark, such as the first alignment mark B1; and the second element may include the third alignment mark, such as the third alignment mark T1. The image acquisition device 300 may be arranged on the machine frame 620. After the movable pick-up stage 100 carries the to-be-bonded first element 400 to the alignment position and the carrier stage carries the to-be-bonded second element 500 to the alignment position, the bonding apparatus 10 may drive the image acquisition device 300 to reach the working position, and that is, the image acquisition device 300 may reach a position below the first element 400 and above the second element 500. The upward-looking image acquisition assembly 310 may capture the first alignment mark B1 corresponding to the first element 400, and the downward-looking image acquisition assembly 320 may capture the third alignment mark T1 corresponding to the second element 500. Subsequently, the first reflection unit 312 may transfer the alignment mark of the first element 400 into the calibration coordinate system, and the second reflection unit 322 may transfer the alignment mark of the second element 500 into the calibration coordinate system. The coordinate information of each alignment mark may be obtained. The coordinate difference may be determined based on the coordinate information, and the coordinate difference may be compared with the calibration information, such that the alignment offset between the first element 400 and the second element 500 may be determined.

At this moment, the first field of view may be an upward-looking viewing angle, and the second field of view may be a downward-looking viewing angle. It is understandable that connection of the image acquisition device 300 with other components may not be limited herein, as long as the image acquisition device 300 is located at the working position between the first element 400 and the second element 500 when capturing the alignment mark of the first element 400 and the alignment mark of the second element 500.

In some embodiments, the image acquisition device 300 may further include an image acquisition driving member 330. An end of the image acquisition driving member 330 may be connected to the machine frame 620, and the other end of the image acquisition driving member 330 may be connected to the image acquisition device 300. Before the first element 400 and the second element 500 are aligned to each other, the image acquisition device 300 may be driven to move from the initial position to the working position, such that the image acquisition device 300 may capture the first alignment mark and the second alignment mark of the first element 400 via the upward-looking image acquisition assembly 310, and may capture the third alignment mark and the fourth alignment mark of the second element 500 via the downward-looking image acquisition assembly 320. After the first element 400 and the second element 500 are aligned with each other, the image acquisition device 300 may be driven to move from the working position to the initial position, such that the image acquisition device 300 may not cause interference when the bonding apparatus performs the subsequent alignment compensation operation or the bonding operation.

In order to better represent a relationship between the first alignment mark and the second alignment mark, a coordinate system may be established.

As shown in FIG. 4, FIG. 4 is a schematic diagram of the calibration coordinate system corresponding to the bonding apparatus according to the present disclosure.

As shown in FIG. 4, after capturing the first alignment mark B1 corresponding to the first element 400 and the third alignment mark T1 corresponding to the second element 500, the first alignment mark B1 and the third alignment mark T1 may be transferred to the same plane via the reflection units. The calibration coordinate system may be defined in the plane based on the calibration information of the image acquisition device 300, such that the coordinate information corresponding to the first alignment mark B1, such as B1 (x_{B1}, y_{B1}), and the coordinate information corresponding to the third alignment mark T1, T1 (x_{T1}, y_{T1}), in the calibration coordinate system may be obtained. The coordinate difference may be calculated based on the coordinate information of each alignment mark and may be compared with the calibration information to determine the alignment offset between the first element and the second element. In this way, a bonding alignment position for the first element 400 and the second element 500 may be determined based on the alignment offset, and the first element 400 and the second element 500 may be bonded to each other according to the bonding alignment position.

In the present embodiment, by arranging the integral image acquisition device, the image acquisition device may capture the alignment mark of the first element and the alignment mark of the second element within the calibration coordinate system of the field of view of the same camera, and the alignment mark of the first element and the alignment mark of the second element may be compared with the calibration information. The bonding apparatus may determine the alignment offset between the first element and the second element. In this way, the bonding apparatus may perform alignment and bonding of the first element and the second element based on the alignment offset. Furthermore, a plurality of alignments may not be performed for each to-be-bonded second element, effectively reducing time consumption, improving the bonding efficiency, and increasing the throughput.

Furthermore, the image acquisition device in the present disclosure may include an upward and downward-looking image acquisition camera and may simultaneously capture the alignment mark from an upward viewing direction and capture the alignment mark from the downward viewing direction. The alignment mark captured from the upward viewing direction and the alignment mark captured from the downward viewing direction may both be transferred into the field of view of the same camera. In this way, distribution of alignment marks of the to-be-bonded first element 400 and the alignment marks of the to-be-bonded second element 500 may not be restricted. Therefore, limitation in the alignment marks of the to-be-bonded first element 400 and the alignment marks of the to-be-bonded second element 500, caused by a size of the field of view of the camera, may be effectively reduced.

Furthermore, for the bonding apparatus in the present disclosure, a closed-loop motion control formed by cooperation of the first driving assembly, the second driving assembly, and a displacement acquisition assembly may be achieved, enabling the carrier stage to achieve nanometer-level precision positioning, such that bonding accuracy may be effectively improved.

Based on the above bonding apparatus, a method for bonding the second element 500 and the first element 400 to each other, using the above bonding apparatus, will be described below.

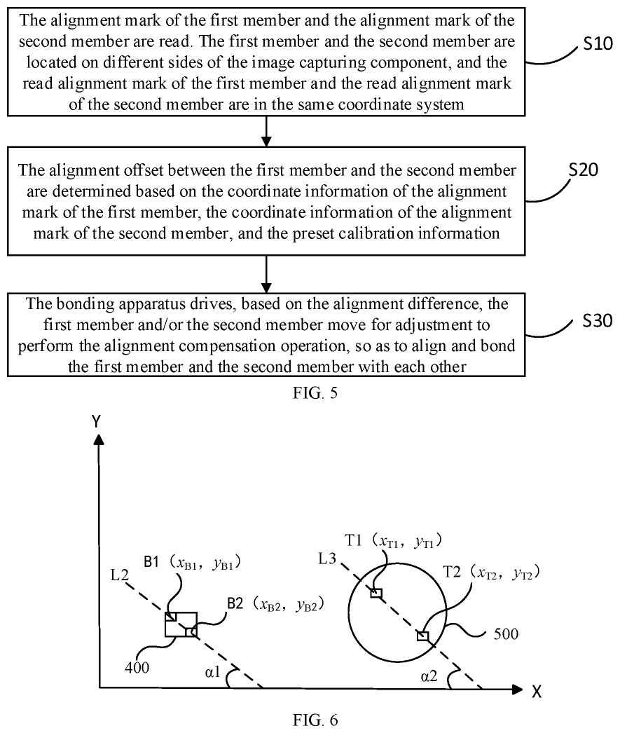

As shown in FIG. 5, FIG. 5 is a flow chart of a bonding method according to the present disclosure. Blocks of the bonding method provided in the present embodiment will be described in detail below by referring to FIG. 5.

Specifically, as shown in FIG. 5, the bonding method may be applied to the bonding apparatus as described in any of the above embodiments. The bonding method may include the following blocks.
S10, the alignment mark of the first element and the alignment mark of the second element may be read. The first element and the second element may be located on different sides of the image acquisition device, and the read alignment mark of the first element and the read alignment mark of the second element may be in the same coordinate system.

In order to reduce the number of times of reading the alignment mark, after obtaining the alignment mark from the upward viewing direction and the alignment mark from the downward viewing direction, all the captured alignment marks may be transferred into the same plane. That is, the corresponding alignment mark from the upward viewing direction and the corresponding alignment mark from the downward viewing direction may be marked within the field of view of the same camera.

Specifically, the movable pick-up stage 100 may be driven to move to the pick-up position and pick up the to-be-bonded first element 400 from the supply platform 700. After picking up the to-be-bonded first element 400, the movable pick-up stage 100 may be driven to move to the alignment position. Simultaneously, the carrier stage 200 may be driven to move the second element 500 to the alignment position. At this moment, the first element 400 may face the second element 500. However, since different members may have different bonding positions, an alignment deviation between the first element 400 and the second element 500 may be formed, and direct bonding between the first element 400 and the second element 500 may not be performed. Therefore, alignment correction may be performed firstly. That is, the image acquisition device 300 may be driven to move to the alignment position, such that the upward-looking image acquisition assembly 310 of the image acquisition device 300 may face the first element 400, and the downward-looking image acquisition assembly 320 of the image acquisition device 300 may face the second element 500. That is, the image acquisition device 300 may be driven to move to the position between the first element 400 and the second element 500, allowing the first element 400 and the second element 500 to appear simultaneously within the field of view of the camera of the image acquisition device 300 and allowing the alignment marks of the first element 400 and the second element 500 to be read. At this moment, the upward-looking image acquisition assembly 310 of the image acquisition device 300 may read the first alignment mark B1 on the to-be-bonded first element 400, and the downward-looking image acquisition assembly 320 of the image acquisition device 300 may read the third alignment mark T1 on the to-be-bonded second element 500.

Further, the calibration coordinate system may be defined based on the calibration information of the image acquisition device 300, and the coordinate information corresponding to the first alignment mark B1 and the second first alignment mark B2 of the first element 400 and the coordinate information corresponding to the third alignment mark T1 and the fourth alignment mark T2 of the second element 500 in the calibration coordinate system may be obtained.

The calibration information may be the coordinate system (measurement) scale of the image acquisition device 300 and may be determined by the internal parameters and/or the external parameters of the image acquisition device 300.

As shown in FIG. 6, FIG. 6 is a schematic view of the bonding apparatus determining the coordinate information of the first element and the coordinate information of the second element according to the present disclosure.

As shown in FIG. 6, the first element may have two alignment marks, such as the first alignment mark B1 and the second alignment mark B2, and the second element may have two alignment marks, such as the third alignment mark T1 and the fourth alignment mark T2. Since the alignment marks of the first element and the alignment marks of the second element are in the same plane, one unified coordinate system, i.e., the calibration coordinate system, may be established to determine a positional relationship among the alignment marks. For example, based on the calibration information corresponding to the image acquisition device, an origin may be defined within the field of view of the camera, so as to define the calibration coordinate system. The calibration coordinate system may include the X-axis and Y-axis. The origin may be an intersection point of boundaries, the X-axis may be a straight line in the X-direction, and the Y-axis may be a straight line in the Y-direction. The coordinate information corresponding to the first alignment mark B1, the second alignment mark B2, the third alignment mark T1, and the fourth alignment mark T2 in the calibration coordinate system may be obtained, such as B1 (x_{B1}, y_{B1}), B2 (x_{B2}, y_{B2}), T1 (x_{T1}, y_{T1}), and T2 (x_{T2}, y_{T2}).

It may be determined whether the first element and the second element are aligned with each other, based on the coordinate information in the calibration coordinate system.
S20, the alignment offset between the first element and the second element may be determined based on the coordinate information of the alignment mark of the first element, the coordinate information of the alignment mark of the second element, and the preset calibration information.

The coordinate information of the alignment mark of the first element may be coordinates of the alignment mark of the first element in the calibration coordinate system. The coordinate information of the alignment mark of the second element may be coordinates of the alignment mark of the second element in the calibration coordinate system.

The preset calibration information may be the coordinate system (measurement) scale determined by the image acquisition device based on the internal parameters thereof.

As shown in FIG. 4, in the calibration coordinate system that includes the X-axis and Y-axis, a first connecting line between the first alignment mark B1 of the first element 400 and the third alignment mark T1 of the second element 500 may be set as L1. Based on the preset calibration information, the coordinate information of the first alignment mark B1 may be determined as B1 (x_{B1}, y_{B1}), and the coordinate information of the third alignment mark T1 may be determined as T1 (x_{T1}, y_{T1}). Furthermore, based on distance information of the first connecting line L1 and an angular relationship between the first connecting line L1 and the X-axis and between the first connecting line L1 and the Y-axis, the difference information between the first element 400 and the second element 500 may be determined.

As shown in FIG. 6, in the calibration coordinate system, a second connecting line between the first alignment mark B1 and the second alignment mark B2 of the first element 400 to be bonded may be set as L2. A first angle may be formed between the second connecting line L2 and the X-axis direction in the calibration coordinate system and may be α1. A third connecting line between the third alignment mark T1 and the fourth alignment mark T2 of the second element 500 to be bonded may be set as L3. A second angle may be formed between the third connecting line L3 and the X-axis in the calibration coordinate system and may be α2. An angular deviation Δα between the to-be-bonded first element 400 and the to-be-bonded second element 500 in the calibration coordinate system may be a difference value between the first angle α1 and the second angle α2, and that is, Δα is an absolute value of (α2−α1). In this way, the alignment offset between the first element 400 and the second element 500 may be determined based on the angular deviation and the coordinate difference between the alignment marks.

Specifically, after obtaining the coordinate information of the first alignment mark B1 and the second alignment mark B2 of the first element and the coordinate information of the third alignment mark T1 and the fourth alignment mark T2 of the second element, difference value calculations may be performed to obtain coordinate differences between the alignment marks. That is, a first X-axis difference Δx1 between the first alignment mark B1 and the third alignment mark T1 may be obtained, i.e., Δx1=an absolute value of (x_{B1}−x_{T1}); a second X-axis difference Δx2 between the second alignment mark B2 and the fourth alignment mark T2 may be obtained, Δx2=the absolute value of (x_{B2}−x_{T2}); a first Y-axis difference Δy1 between the first alignment mark B1 and the third alignment mark T1 on the Y-axis may be obtained, Δy1=the absolute value of (y_{B1}−y_{T1}); a second Y-axis difference Δy2 between the second alignment mark B2 and the fourth alignment mark T2 on the Y-axis may be obtained, Δy2 =the absolute value of (y_{B2}−y_{T2}). An angular deviation value Δα between the second connecting line L2 and the third connecting line L3 may be obtained, Δα=the absolute value of (α2−α1). Then, the first X-axis difference Δx1, the second X-axis difference Δx2, the first Y-axis difference Δy1, the second Y-axis difference Δy2, and the angular deviation value Δα may be compared with the coordinate system (measurement) scale, such that the alignment offset between the first element 400 and the second element 500 may be determined.

That is, the bonding alignment position for the first element 400 and the second element 500 may be determined based on the first X-axis difference Δx1, the second X-axis difference Δx2, the first Y-axis difference Δy1, the second Y-axis difference Δy2, and the angular deviation value Δα. In this way, the above difference may be compared with the preset calibration information of the image acquisition device 300 to determine the alignment offset between the first element 400 and the second element 500.

In some embodiments, a height difference between the first element 400 and the second element 500 may be determined based on a first distance between the first element 400 and the image acquisition device 300 and a second distance between the second element 500 and the image acquisition device 300. Subsequently, the first element 400 and the second element 500 may be moved in the height direction based on the height difference. For example, the first element 400 may be moved downward to be in contact with the second element 500, preventing any damage to the first element 400 and the second element 500 due to the first element 400 being moved excessively long, or preventing failure in complete bonding due to the first element 400 being moved insufficiently.
S30, the bonding apparatus may drive, based on the alignment offset, the first element and/or the second element to move for adjustment to perform the alignment compensation operation, so as to align and bond the first element and the second element with each other.

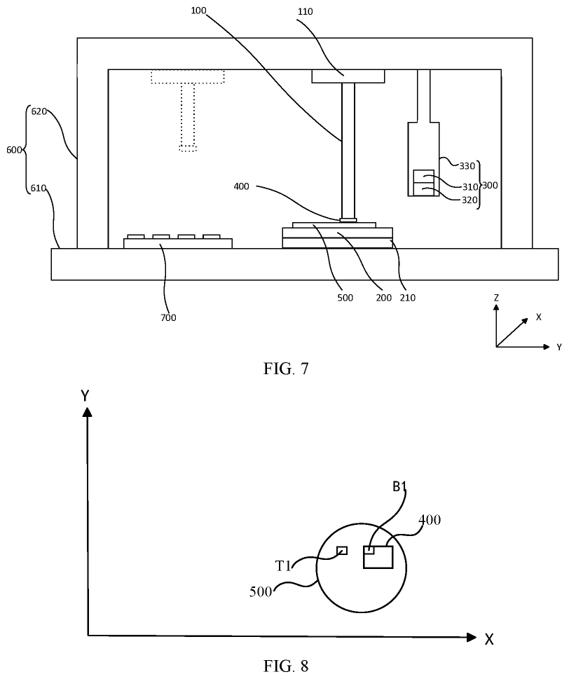

As shown in FIG. 7 and FIG. 8, FIG. 7 is a schematic view of a process of the bonding apparatus bonding the first element to the preset surface position of the second element according to the present disclosure; and FIG. 8 is a schematic view of the coordinate information of the first element in the calibration coordinate system, when the first element being bonded to the preset surface position of the second element.

In order to align the first element with the second element, the movable pick-up stage 100 may be driven to move the first element 400, or the carrier stage 200 may be driven to move the second element. That is, in response to the bonding apparatus performing the alignment compensation operation, the first element 400 and the second element 500 may be driven to reach the alignment position, and the first element 400 and the second element 500 at the alignment position may be adjusted, such that the first element 400 and the second element 500 at the alignment position may be aligned with each other in the height direction. The upward-looking image acquisition unit of the image acquisition device may be used to identify the alignment mark of the first element 400, and the downward-looking image acquisition assembly 320 of the image acquisition device may be used to identify the alignment mark of the second element 500. The alignment mark of the first element 400 and the alignment mark of the second element 500 may be transferred to the same plane to obtain the corresponding coordinate differences. The comparison result between the coordinate differences and the preset calibration information may be used as the alignment offset for performing the alignment compensation operation, such that the first element 400 and the second element 500 may be aligned with each other.

In some embodiments, in response to the bonding apparatus performing the bonding operation, the first element 400 may be configured as a to-be-bonded chip or wafer, and the second element 500 may be configured as a to-be-bonded chip or wafer. The movable pick-up stage and/or the carrier stage may be used to move the first element 400 and the second element 500 to reach the alignment position, and the alignment compensation operation may be performed to enable the first element 400 and the second element 500 at the alignment position to be aligned with each other.

The movable pick-up stage 100 and/or the carrier stage 200 may be adjusted based on the alignment offset, so as to perform the alignment compensation operation on the first element 400 and the second element 500 at the alignment position. Furthermore, the movable pick-up stage 100 may be moved in the height direction to drive the first element 400 and the second element 500 to reach the bonding position. Alternatively, the movable pick-up stage 100 and/or the carrier stage 200 may be moved in the height direction to drive the first element 400 and the second element 500 to reach the bonding position, and at the same time, the movable pick-up stage 100 and/or the carrier stage 200 may be adjusted based on the alignment offset, so as to perform the alignment compensation operation on the first element 400 and the second element 500.

In some embodiments, after obtaining the X-axis coordinate difference and the Y-axis coordinate difference, the movable pick-up stage 100 may be driven to move in the X-axis direction based on the X-axis coordinate difference and driven to move in the Y-axis direction based on the Y-axis coordinate difference.

Further, the movable pick-up stage 100 may further be driven for fine adjustment based on the angular deviation value Δα, and the alignment position for the first element 400 and the second element 500 may be determined based on the preset calibration information of the image acquisition device 300, enabling the first element 400 and the second element 500 to be aligned with each other.

In some embodiments, after obtaining the X-axis coordinate difference and the Y-axis coordinate difference, the carrier stage 200 may be driven to move in the X-axis direction based on the X-axis coordinate difference and driven to move in the Y-axis direction based on the Y-axis coordinate difference.

In some embodiments, after obtaining the X-axis coordinate difference and the Y-axis coordinate difference, the carrier stage 200 and the movable pick-up stage 100 may be simultaneously driven to move in the X-axis direction based on the X-axis coordinate difference and simultaneously driven to move in the Y-axis direction based on the Y-axis coordinate difference.

Further, the carrier stage 200 and the movable pick-up stage 100 may be simultaneously driven for fine adjustment based on the angular deviation value Δα, and the alignment position for the first element 400 and the second element 500 may be determined based on the preset calibration information of the image acquisition device 300, enabling the first element 400 and the second element 500 to be aligned with each other.

As shown in FIG. 7, after the first element 400 and the second element 500 are aligned with each other, the movable pick-up stage 100 may be driven to move in the height direction, such as moving downward, based on the height difference, to carry the first element 400 to move downward. The moved-down first element 400 may contact and may be bonded with the second element 500 on the carrier stage 200. The coordinate information of the first alignment mark B1 of the first element 400 and the third alignment mark T1 of the second element 500 in the calibration coordinate system, after the first element 400 and the second element 500 are bonded to each other, may be shown in FIG. 8.

In some embodiments, before aligning the first element 400 and the second element 500 with each other, the image acquisition device 300 of the bonding apparatus may be driven to move from the initial position to the working position, such that the image acquisition device 300 may read the alignment mark of the first element and the alignment mark of the second element at the alignment position. After the first element 400 and the second element 500 are aligned with each other, the image acquisition device 300 may be driven to move from the working position to the initial position, facilitating the subsequent alignment compensation operation or bonding operation to be performed, preventing the first element 400 from being blocked during moving downward.

Specifically, after the first element 400 and the second element 500 are aligned with each other and before the first element 400 moves in the height direction, such as before moving downward, the bonding apparatus 10 may drive the image acquisition device 300 to move from the working position to the initial position. Furthermore, the second driving assembly 210 may be driven to carry the first element 400 on the movable pick-up stage 100 to move downward. The downward movement may be performed based on the height difference. In this way, the first element 400 may contact and may be bonded with the second element on the carrier stage 200.

In the present embodiment, by transferring the captured alignment mark of the first element and the captured alignment mark of the second element into the same coordinate system to determine the coordinate information of the alignment mark of the first element and the alignment mark of the second element within the same coordinate system, the alignment offset between the first element and the second element may be determined based on the coordinate information. Subsequently, the first element and/or the second element may be adjusted based on the alignment offset to enable the first element and the second element to be aligned with each other. That is, the bonding method in the present disclosure may be applied to the bonding apparatus described above, and therefore, the bonding method may achieve the same technical effects as the bonding apparatus does, which will not be repeated here.

The foregoing may merely be some embodiments of the present disclosure and may not be intended to limit the scope of the present disclosure. Any equivalent structures or equivalent process transformations made by using the contents of the description and the accompanying drawings of the present disclosure, or directly or indirectly applied to other related technical fields, may be included within the scope of patent protection of the present disclosure.

What is claimed is:

1. A bonding apparatus, comprising:
a movable pick-up stage, configured to move a first element;
a carrier stage, configured to move a second element;
an image acquisition device, configured to read at least one alignment mark of the first element and at least one alignment mark of the second element that are respectively located on two sides of the image acquisition device; wherein, the read at least one alignment mark of the first element and the read at least one alignment mark of the second element are located in one coordinate system; the bonding apparatus is configured to determine an alignment offset between the first element and the second element based on coordinate information of the at least one alignment mark of the first element, coordinate information of the at least one alignment mark of the second element, and preset calibration information of the image acquisition device;
wherein, the bonding apparatus is configured to drive at least one of the movable pick-up stage and the carrier stage to move for adjustment to perform an alignment compensation operation based on the alignment offset, enabling the first element and the second element to be aligned and bonded to each other.

2. The bonding apparatus according to claim 1, wherein, the image acquisition device is an upper-and-downward-looking image acquisition device, comprising:
an upward-looking image acquisition assembly, configured to identify, in response to the image acquisition device being driven to reach a working position, at least one of the at least one alignment mark of the first element in a calibration coordinate system;
a downward-looking image acquisition assembly, configured to identify, in response to the image acquisition device being driven to reach the working position, at least one of the at least one alignment mark of the second element in the calibration coordinate system;
wherein, the bonding apparatus is configured to: determine a coordinate difference based on the at least one alignment mark of the first element and the at least one alignment mark of the second element; and determine the alignment offset between the first element and the second element based on the coordinate difference and the preset calibration information of the image acquisition device.

3. The bonding apparatus according to claim 2, wherein,
the upward-looking image acquisition assembly comprise:
an upward-looking image acquisition unit, configured to identify, in response to the image acquisition device being driven to reach the working position, the at least one alignment mark of the first element;
a first reflection unit, configured to transfer, in response to the upward-looking image acquisition unit identifying the at least one alignment mark of the first element, the at least one alignment mark of the first element into the calibration coordinate system;
the downward-looking image acquisition assembly comprises:
a downward-looking image acquisition unit, configured to identify, in response to the image acquisition device being driven to reach the working position, the at least one alignment mark of the second element;
a second reflection unit, configured to transfer, in response to the downward-looking image acquisition unit identifying the at least one alignment mark of the second element, the at least one alignment mark of the second element into the calibration coordinate system.

4. The bonding apparatus according to claim 1, wherein,
the bonding apparatus is further configured to adjust, based on the at least one alignment mark of the first element and the at least one alignment mark of the second element that are identified by the image acquisition device, the first element and the second element located at an alignment position, for aligning the first element and the second element at the alignment position in a height direction.

5. The bonding apparatus according to claim 4, wherein,
in response to the bonding apparatus performing the alignment compensation operation, the first element and the second element that are aligned with each other at the alignment position are configured to move to reach a bonding position;
the image acquisition device is configured to: identify the at least one alignment mark of the first element and the at least one alignment mark of the second element at the bonding position; obtain a difference between the at least one alignment mark of the first element and the at least one alignment mark of the second element; and take a comparison result between the difference and the preset calibration information as the alignment offset to perform the alignment compensation operation.

6. The bonding apparatus according to claim 5, wherein,
in response to the bonding apparatus performing a bonding operation, the bonding apparatus is configured to: adjust at least one of the movable pick-up stage and the carrier stage based on the alignment offset, so as to perform the alignment compensation operation on the first element and the second element at the alignment position; and move at least one of the movable pick-up stage and the carrier stage in the height direction to drive the first element and the second element to reach the bonding position.

7. The bonding apparatus according to claim 5, wherein,
in response to the bonding apparatus performing the bonding operation, the bonding apparatus is configured to: move the at least one of movable pick-up stage and the carrier stage in the height direction to drive the first element and the second element to reach the bonding position, and at the same time, adjust at least one of the movable pick-up stage and the carrier stage based on the alignment offset to perform the alignment compensation operation on the first element and the second element.

8. The bonding apparatus according to claim 6, wherein,
after aligning the first element and the second element at the alignment position with each other and before moving at least one of the first element and the second element in the height direction, the image acquisition device is configured to be driven to reach an initial position.

9. The bonding apparatus according to claim 1, further comprising: a machine station, comprising a base and a machine frame, wherein,
the machine frame is disposed on the base, the movable pick-up stage is disposed on the machine frame, the carrier stage is disposed on the base;
at least one of the movable pick-up stage and the carrier stage is movable along a first direction, a second direction, and a height direction, wherein, the first direction and the second direction are two intersecting directions and are perpendicular to the height direction; at least one of the movable pick-up stage and the carrier stage is rotatable in a vertical plane perpendicular to a horizontal plane, enabling a horizontal state of at least one of the movable pick-up stage and the carrier stage to be adjustable, wherein, the horizontal plane is a plane on which the first direction and the second direction extend.

10. The bonding apparatus according to claim 1, wherein, the read at least one alignment mark of the first element and the read at least one alignment mark of the second element being located in one coordinate system refers to the read at least one alignment mark of the first element and the read at least one alignment mark of the second element being transferred to one field of view of one camera.

11. The bonding apparatus according to claim 1, wherein, fine adjustment is further performed on at least one of the movable pick-up stage and the carrier stage to enable the first element and the second element to be aligned with each other; the fine adjustment is performed based on an angular deviation between the first element and the second element in the coordinate system.

12. A bonding method, applied to a bonding apparatus, the bonding method comprising:
reading at least one alignment mark of a first element and at least one alignment mark of a second element, wherein, the first element and the second element are located on different sides of an image acquisition device of the bonding apparatus, and the read at least one alignment mark of the first element and the read at least one alignment mark of the second element are located in one coordinate system;
determining an alignment offset between the first element and the second element based on coordinate information of the at least one alignment mark of the first element, coordinate information of the at least one alignment mark of the second element, and preset calibration information of the image acquisition device;
driving, by the bonding apparatus, at least one of the first element and the second element to move for adjustment to perform an alignment compensation operation based on the alignment offset, so as to enable the first element and the second element to be aligned and bonded to each other.

13. The bonding method according to claim 12, wherein, the reading at least one alignment mark of a first element and at least one alignment mark of a second element, comprises:
in response to the bonding apparatus performing a bonding operation, driving a movable pick-up stage of the bonding apparatus to pick up and move the first element to an alignment position, and driving a carrier stage of the bonding apparatus to carry and move the second element to the alignment position; and
driving the image acquisition device of the bonding apparatus to reach a working position and to identify the alignment mark of the first element and the alignment mark of the second element in a calibration coordinate system.

14. The bonding method according to claim 12, wherein,
in response to the bonding apparatus performing the alignment compensation operation, the first element and the second element are driven to reach an alignment position, and the first element and the second element at the alignment position are adjusted, enabling the first element and the second element at the alignment position to be aligned with each other in a height direction.

15. The bonding method according to claim 12, wherein,
in response to the bonding apparatus performing the alignment compensation operation, the image acquisition device of the bonding apparatus is driven to reach a working position;
an upward-looking image acquisition assembly of the image acquisition device identifies at least one of the at least one alignment mark of the first element, and a downward-looking image acquisition assembly of the image acquisition device identifies at least one of the at least one alignment mark of the second element;
the at least one alignment mark of the first element and the at least one alignment mark of the second element are transferred into the one coordinate system to obtain a coordinate difference between the at least one alignment mark of the first element and the at least one alignment mark of the second element; and
a comparison result between the coordinate difference and the preset calibration information is used as the alignment offset to perform the alignment compensation operation.

16. The bonding method according to claim 12, wherein,
in response to the bonding apparatus performing a bonding operation, the first element is configured as a to-be-bonded chip or wafer, and the second element is configured as a to-be-bonded wafer or chip;
at least one of a movable pick-up stage and a carrier stage of the bonding apparatus moves the first element and the second element to reach an alignment position, and the alignment compensation operation is performed to enable the first element and the second element driven to the alignment position to be aligned with each other.

17. The bonding method according to claim 16, wherein, at least one of the movable pick-up stage and the carrier stage of the bonding apparatus moving the first element and the second element to reach the alignment position, and the alignment compensation operation being performed to enable the first element and the second element driven to the alignment position to be aligned with each other, comprises:
adjusting at least one of the movable pick-up stage and the carrier stage based on the alignment offset to perform the alignment compensation operation on the first element and the second element at the alignment position, and moving at least one of the movable pick-up stage and the carrier stage in a height direction to drive the first element and the second element to reach a bonding position.

18. The bonding method according to claim 16, wherein, at least one of the movable pick-up stage and the carrier stage of the bonding apparatus moving the first element and the second element to reach the alignment position, and the alignment compensation operation being performed to enable the first element and the second element driven to the alignment position to be aligned with each other, comprises:
moving at least one of the movable pick-up stage and the carrier stage in a height direction to drive the first element and the second element to reach a bonding position, and at the same time, adjusting at least one of the movable pick-up stage and the carrier stage based on the alignment offset to perform the alignment compensation operation on the first element and the second element.

19. The bonding method according to claim 12, wherein, before the first element and the second element are aligned with each other, the bonding method further comprises:
driving the image acquisition device of the bonding apparatus to move from an initial position to a working position to read the at least one alignment mark of the first element and the at least one alignment mark of the second element at an alignment position;
after the first element and the second element are aligned with each other, the bonding method further comprises:
driving the image acquisition device to move from the working position to the initial position to leave a space for the alignment compensation operation or a bonding operation to be performed.

20. The bonding method according to claim 12, wherein, fine adjustment is further performed on at least one of the movable pick-up stage and the carrier stage to enable the first element and the second element to be aligned with each other; the fine adjustment is performed based on an angular deviation between the first element and the second element in the coordinate system.
